(19) United States
(12) Patent Application Publication
(10) Pub. No.: US 2025/0132419 A1
(43) Pub. Date: Apr. 24, 2025

(54) LOOP-BASED THERMAL MANAGEMENT METHOD, APPARATUS, DEVICE, AND SYSTEM

(71) Applicant: SHENZHEN INFYPOWER CO., LTD, Shenzhen (CN)

(72) Inventors: Yujia Yang, Shenzhen (CN); Xing Yue, Shenzhen (CN); Jun Jun Deng, Shenzhen (CN); Jun Zhang, Shenzhen (CN)

(21) Appl. No.: 19/007,612

(22) Filed: Jan. 2, 2025

Related U.S. Application Data
(63) Continuation-in-part of application No. PCT/CN2023/085977, filed on Apr. 3, 2023.

(30) Foreign Application Priority Data
Jul. 15, 2022 (CN) 202221838204.9

(51) Int. Cl. H01M 10/6568; H01M 10/613; H01M 10/627; H01M 10/633; H01M 10/651; H01M 10/6551

(52) U.S. Cl. CPC H01M 10/6568; H01M 10/613; H01M 10/627; H01M 10/633; H01M 10/651; H01M 10/6551

(57) ABSTRACT

The present application provides a loop-based thermal management method, apparatus, device, and system. A thermal management capacity deviation value in a current sampling stage is determined according to a rate of change of temperature difference and a temperature difference in a current sampling stage, and a thermal management capacity value is calculated according to a thermal management capacity value in a previous sampling stage and the deviation value. A corresponding number of chillers to be operated in the current sampling stage is determined according to the thermal management capacity value in the current sampling stage, and a target output cooling capacity of the chillers is determined according to a preset Cooling demand control strategy to control the chillers. This technical solution can reduce the energy consumption of the whole system. Furthermore, centralized control of the water loop improves the reliability and cooling efficiency of the battery cabinet.

### CROSS-REFERENCE TO RELATED APPLICATIONS

This application is a continuation-in-part (CIP) application based upon the International Application PCT/CN2023/085977, filed Apr. 3, 2023, the entire content of which is incorporated herein by reference. This application is also based upon and claims the benefits of priority from the prior Chinese Patent Application No. 202221838204.9, filed Jul. 15, 2022, the entire content of which is incorporated herein by reference.

### TECHNICAL FIELD

The present application relates to the field of Stored energy thermal management, in particular to a loop-based thermal management method, apparatus, device, and system.

### BACKGROUND

In recent years, lithium battery energy storage systems have developed rapidly and continue to expand into larger markets at a high pace. As the market grows, the requirements for energy storage systems have become increasingly clear and stringent. Among these, high reliability, long lifespan, and high efficiency in energy saving are some of the core demands. Beyond standard considerations such as electrical safety design and material lifespan, the key factor influencing the reliability and lifespan of battery cells lies in thermal management design. A well-designed thermal management system ensures that the battery cells operate within an appropriate temperature range, thereby achieving a longer lifespan, while the thermal management system directly affects the energy-saving and safety performance of energy storage systems.

At present, most battery cabinet thermal management systems are traditional cooling devices designed in a one-to-one configuration and installed inside the cabinets. This design has several drawbacks, including inconvenient maintenance, low reliability, and poor energy efficiency. Furthermore, the heat exchanger area of the cooling equipment is limited by the internal space of the cabinet and installation constraints, which reduces energy efficiency and shortens the duration of utilizing natural cooling, posing significant limitations in practical use. Additionally, the regulation of internal chillers in battery cabinet thermal management systems often relies on fixed-frequency operation or simple on-off control. This approach cannot dynamically adjust cooling output according to load demand, frequently resulting in overcooling or insufficient cooling, resulting in defects including poor temperature control and high energy consumption.

### SUMMARY

An object of the present application is to provide a loop-based thermal management method, device, apparatus, and system to address, at least to some extent, the deficiencies in the related art.

In a first aspect of the present application, there is provided loop-based thermal management method, applied to a loop-based thermal management system comprising a water supply pipe loop, a water return pipe loop, and a plurality of chillers, the loop-based thermal management method comprising:

deriving a rate of change of temperature difference according to a temperature difference in a current sampling stage and the temperature difference in a previous sampling stage; wherein the temperature difference is a difference between a temperature of the water supply pipe loop and a temperature of the water return pipe loop;
determining a thermal management capacity deviation value in the current sampling stage according to the rate of change of temperature difference and the temperature difference in the current sampling stage;
calculating a thermal management capacity value in the current sampling stage according to the thermal management capacity deviation value in the current sampling stage and a thermal management capacity value in the previous sampling stage;
determining a corresponding number of chillers to be operated in the current sampling stage according to the thermal management capacity value in the current sampling stage; and
determining a target output cooling capacity of the chillers according to a predetermined Cooling demand control strategy, and controlling each of the chillers in target chillers corresponding to the number of chillers to be operated to enter into an operating state according to the target output cooling capacity.

In a second aspect of the present application, there is further provided a loop-based thermal management apparatus comprising:

a module of rate of change of temperature difference configured to derive a rate of change of temperature difference according to a temperature difference in a current sampling stage and the temperature difference in a previous sampling stage; wherein the temperature difference is a difference between a temperature of the water supply pipe loop and a temperature of the water return pipe loop;

a thermal management capability deviation value module configured to determine a thermal management capacity deviation value in the current sampling stage according to the rate of change of temperature difference and the temperature difference in the current sampling stage;

a thermal management capability value module configured to calculate a thermal management capacity value in the current sampling stage according to the thermal management capacity deviation value in the current sampling stage and a thermal management capacity value in the previous sampling stage;

a calculating module configured to determine a corresponding number of chillers to be operated in the current sampling stage according to the thermal management capacity value in the current sampling stage; and an operation control module configured to determine a target output cooling capacity of the chillers according to a predetermined Cooling demand control strategy, and control each of the chillers in target chillers corresponding to the number of chillers to be operated to enter into an operating state according to the target output cooling capacity.

In a third aspect of the present application, there is also provided an electronic device comprising a memory, a processor, and a bus;
wherein the bus is configured to realize a connection communication between the memory and the processor;
the processor is configured to execute a computer program stored in the memory;
and the processor, when executing the computer program, realizes the steps in the loop-based thermal management method

In a fourth aspect of the present application, there is further provided a loop-based thermal management system comprising a battery cabinet, a water supply pipe loop, and a water return pipe loop; the battery cabinet comprises a cabinet, a battery pack, chillers, a heat dissipation group, and bypass valves; the battery pack, the chiller, the heat dissipation group, and the bypass valve are provided in the cabinet, and the heat dissipation group is provided on a peripheral side of the battery pack; a first inlet end of the heat dissipation group is detachably connected to the water supply pipe loop, and a first water outlet end of the heat dissipation group is detachably connected to the water return pipe loop; a second water outlet end of the chillers is detachably connected to the water supply pipe loop, and a second water inlet end of the chillers is detachably connected to the water return pipe loop, and a by-pass valve is provided between the first water inlet end and the second water outlet end and a by-pass valve is provided between the first water outlet end and the second water inlet end; the loop-based thermal management system is configured to realize the steps in the loop-based thermal management method of the first aspect.

The beneficial effects of the loop-based thermal management method, apparatus, device, and system of the present application are as follows. Firstly, by combining a water loop control strategy with a Cooling demand control strategy, it is possible to determine the number of chillers to be operated and the target output cooling capacity that are compatible with the current sampling stage, and thus control the number of chillers to be operated and the output cooling capacity of the corresponding chillers on the basis of the confirmed data, so as to realize precise adjustment. In other words, compared with the traditional thermal management method, the present application is able to adjust the working state of the chillers in real time according to the heat dissipation situation inside the loop and the load demand, significantly improving the accuracy of the cooling capacity distribution and the system response speed, effectively avoid overcooling or undercooling, and reduce the energy consumption of the whole system, thus achieving the energy-saving effect. Secondly, through the water supply pipe loop as well as the water return pipe loop, all the individual heat management systems (chillers) within the loop are united for centralized control. After the centralized control through the water loop, the reliability of the battery cabinets in the whole loop is improved, even if some of the chillers in the battery cabinets are damaged, they can still be used to provide cooling for the faulty battery cabinets through the water supply pipe loop and the water return pipe loop by other chillers in normal operation, so that the battery packs do not have to shut down and continue to run while waiting for the repair process. After centralized control through the water loop, in the face of most cases of some battery cabinets standby, the whole chillers can provide the cooling function for the remaining battery cabinets in operation, to increase the heat exchanger area in disguise thereby increasing the cooling efficiency. Besides, due to the larger heat exchanger area, making the thermal management system within the loop naturally cooled for a longer and more energy-efficient period of time. By closing and opening the bypass valves in the battery cabinet, it is possible to take into account the single operation of the battery cabinet and the joint operation of many battery cabinets.

### BRIEF DESCRIPTION OF THE DRAWINGS

In order to more clearly illustrate the technical solutions in the embodiments or related art of the present application, the accompanying drawings to be used in the description of the embodiments or prior art will be briefly introduced below. Obviously, the accompanying drawings in the following description are only some of the embodiments of the present application, and for the person skilled in the field, other accompanying drawings may be obtained according to these drawings without paying creative labor.

FIG. 1 shows a schematic flowchart of a loop-based thermal management method according to an embodiment of the present application.

FIG. 2 shows a schematic diagram of the principle of the loop-based thermal management system according to an embodiment of the present application.

FIG. 3 shows a schematic diagram of a battery cabinet according to an embodiment of the present application.

FIG. 4 shows a schematic diagram of the operation of the loop-based thermal management system according to an embodiment of the present application after the chillers inside a specific battery cabinet are damaged.

FIG. 5 shows a schematic diagram of the operation of the loop-based thermal management system according to an embodiment of the present application when only one battery cabinet is charged or discharged.

FIG. 6 shows a schematic diagram of the loop-based thermal management system according to an embodiment of the present application in which the AB section of a water pipe of the water supply pipe loop is damaged and needs to be serviced.

FIG. 7 shows a schematic diagram of the maintenance of the AB section of the water pipe by means using a service valve according to an embodiment of the present application.

FIG. 8 shows a schematic diagram of the module connection of a loop-based thermal management apparatus according to an embodiment of the present application.

FIG. 9 shows a schematic diagram of structural connections within an electronic device according to an embodiment of the present application.

### DETAILED DESCRIPTION OF THE EMBODIMENTS

Embodiments of the present application are described in detail below, and examples of the embodiments are shown in the accompanying drawings. The same or similar symbols throughout indicate the same or similar elements or elements having the same or similar functions. The embodiments described below by reference to the accompanying drawings are exemplary and are intended to be used for explaining the present application and are not to be construed as a limitation of the present application, and all other embodiments according to the embodiments in the present application that are obtained by a person of ordinary skill in the art without creative labor fall within the scope of protection of the present application.

Furthermore, the terms “first” and “second” are used for descriptive purposes only, and are not to be construed as indicating or implying relative importance or implicitly specifying the number of technical features indicated. Thus, a feature defined with the terms “first”, and “second” may expressly or implicitly include one or more such features. In the description of the present application, “more than one” means two or more, unless otherwise expressly and specifically limited, and “*” indicates a multiplication operation in arithmetic.

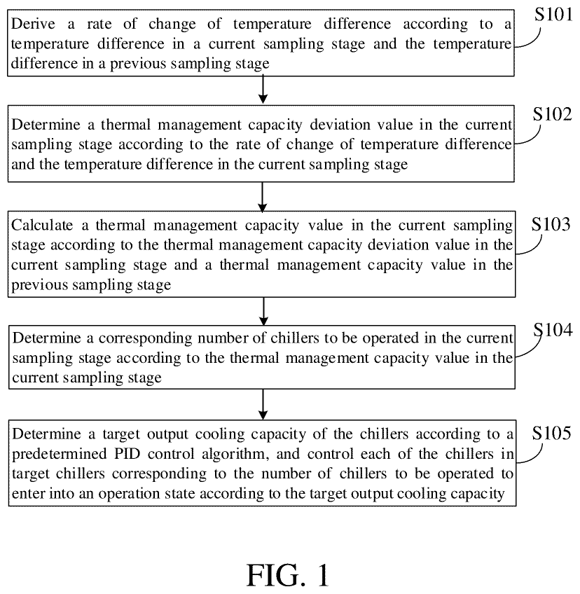

As shown in FIG. 1, an embodiment of the present application provides a loop-based thermal management method, applied to a loop-based thermal management system including a water supply pipe loop, a water return pipe loop, and a plurality of chillers. The loop-based thermal management method includes the following steps.

Step S101, a rate of change of temperature difference derived according to a temperature difference in a current sampling stage and a temperature difference in a previous sampling stage.

Specifically, the loop-based thermal management system starts the water supply pipe loop and the water return pipe loop, and when cooling the battery cabinets in the loop, it prioritizes starting up all the chillers in the loop. After a sampling stage (e.g., 1 minute), the rate of change of the temperature difference, ddt(k), can be derived as the difference between the temperature difference dt(k−1) in the previous sampling stage and the temperature difference dt (k) in the current sampling stage, i.e., according to ddt

(k)=dt(k−1)−dt(k).

It should be noted that the temperature difference in each sampling stage is the difference between a temperature of the supply pipe loop temperature and a temperature of the water return pipe loop, i.e., the temperature difference reflects the effect of the cold water in the loop absorbing heat from the heat load. In general, the larger temperature difference indicates that the return water temperature is higher and the heat load in the system is releasing more heat (which may require an increase in the chiller's cooling output). Besides, the smaller temperature difference indicates that the return water temperature is close to the supply water temperature, the heat load in the system is low or the chiller output is too high.

As a result, the rate of change of the temperature difference derived from the temperature difference between two adjacent sampling stages can reflect the trend of the thermal load in the system and the dynamic matching of the chiller cooling output with the load demand. Generally, the larger rate of change of the temperature difference (larger absolute value) indicates that the temperature difference of the system is changing more quickly and indicates that the thermal load fluctuates drastically or that the chiller regulating speed is insufficient, and that it is necessary to adjust the chiller cooling output or the chiller operating status quickly to ensure that the system is running at a higher temperature. Besides, the smaller rate of change of the temperature difference (smaller absolute value) indicates that the system temperature difference changes more slowly, and indicates that the heat load is more stable, the cold output is close to the load demand, the system is close to the dynamic balance, the chiller regulates less pressure, and the energy consumption is lower. In summary, the size of the rate of the change of temperature difference is an important indicator of the system's dynamic regulation capability, and the rate of change of temperature difference derived in step S101 can be used as the basic data for the subsequent precise regulation of the chillers.

Step S102, a thermal management capability deviation value in the current sampling stage is determined according to the rate of change of temperature difference and the temperature difference in the current sampling stage.

Specifically, after obtaining the rate of change of temperature difference ddt and the temperature difference dt (k) in the current sampling stage, according to a pre-stored mapping relationship in the form of a table (as shown in Table 1 below, which contains a temperature difference, a rate of change of temperature difference, a capability value, and a fuzzy state), the fuzzy state corresponding to the rate of change of temperature difference ddt and the temperature difference dt (k) in the current sampling stage, respectively, can be derived. That is, according to the preset mapping relationship between the rate of change of temperature difference and the fuzzy state and the mapping relationship between the temperature difference and the fuzzy state in Table 1, the first fuzzy state corresponding to the rate of change of temperature difference and the second fuzzy state corresponding to the temperature difference in the current sampling stage are determined, respectively.

After the corresponding fuzzy state is determined, according to the first fuzzy state and the second fuzzy state, and in combination with a predetermined mapping relationship between the fuzzy state and the deviation value of the thermal management capability (the mapping relationship is in the form of a table, as shown in Table 2 below), the thermal management capability deviation value in the current sampling stage, Au (k), is determined.

The fuzzy states include Positive Large Large (PLL), Positive Large (PL), Positive Medium (PM), Positive Small (PS), Zero (ZO), Negative Small (NS), Negative Medium (NM), and Negative Large (NL).

TABLE 1

| | | | | Thermal management | |
|---|---|---|---|---|---|
| Temperature difference (dt) | | Temperature variation rate | | capacity output | |
| affiliation determination | | ddt affiliation determination | | determination | |
| Positive | dt ≥ 5 | Positive | ddt > 0.8 | Positive | 3 |
| Large Large | | Large Large | | Large (PL) | |
| (PLL) | | (PLL) | | | |
| Positive | 3 ≤ dt < 5 | Positive | 0.4 < ddt ≤ 0.8 | Positive | 2 |
| Large (PL) | | Large (PL) | | Medium (PM) | |
| Positive | 1.5 ≤ dt < 3 | Positive | 0.2 < ddt ≤ 0.4 | Positive | 1 |
| Medium (PM) | | Medium (PM) | | Small (PS) | |
| Positive | 0.5 ≤ dt < 1.5 | Positive | 0.1 < ddt ≤ 0.2 | Zero (ZO) | 0 |
| Small (PS) | | Small (PS) | | | |
| Zero (ZO) | −0.5 < dt < 0.5 | Zero (ZO) | −0.1 ≤ ddt ≤ 0.1 | Negative | −1 |
| | | | | Small (NS) | |
| Negative | −1 < dt ≤ −0.5 | Negative | −0.3 < ddt < −0.1 | Negative | −2 |
| Small (NS) | | Small (NS) | | Medium (NM) | |
| Negative | −2 < dt ≤ −1 | Negative | ddt ≤ −0.3 | Negative | −3 |
| Medium (NM) | | Medium (NM) | | Large (NL) | |
| Negative | dt ≤ −2 | / | / | / | / |
| Large (NL) | | | | | |

In Table 1 above, the corresponding fuzzy state may be determined when the temperature difference is in different value range intervals. For example, when the temperature difference is 5, the corresponding fuzzy state is positive large large. The corresponding fuzzy state may be determined when the rate of change of the temperature difference is in different value range intervals. For example, when the rate of change of the temperature difference is-0.1, the corresponding fuzzy state is zero.

TABLE 2

| | Temperature difference | | | | | | | |
|---|---|---|---|---|---|---|---|---|
| | Positive | | | | | | | |
| | Large | Positive | Positive | Positive | | Negative | Negative | Negative |
| Rate of | Large | Large | Medium | Small | Zero | Small | Medium | Large |
| change | PLL | PL | PM | PS | ZO | NS | NM | NL |
| Positive | 0 | 0 | −1 | −2 | −3 | −3 | −3 | −3 |
| Large | | | | | | | | |
| Large | | | | | | | | |
| PLL | | | | | | | | |
| Positive | 1 | 0 | 0 | −1 | −2 | −3 | −3 | −3 |
| Large | | | | | | | | |
| PL | | | | | | | | |
| Positive | 2 | 1 | 0 | 0 | −1 | −2 | −3 | −3 |
| Medium | | | | | | | | |
| PM | | | | | | | | |
| Positive | 3 | 2 | 1 | 0 | 0 | −1 | −3 | −3 |
| Small PS | | | | | | | | |
| Zero ZO | 3 | 3 | 1 | 1 | 0 | −1 | −2 | −3 |
| Negative | 3 | 3 | 2 | 1 | 0 | 0 | −1 | −2 |
| Small NS | | | | | | | | |
| Negative | 3 | 3 | 3 | 2 | 1 | 0 | 0 | −1 |
| Medium | | | | | | | | |
| NM | | | | | | | | |

In Table 2 above, when the fuzzy state of the temperature difference and the fuzzy state of the rate of change of temperature difference are derived, the corresponding thermal management capability deviation value Au (k) in the current sampling stage is derived according to the mapping relationship between the fuzzy state and the thermal management capability deviation value in the form of a table. For example, when the fuzzy state of the temperature difference is positive large large and the fuzzy state of the rate of change of the temperature difference is zero, the corresponding thermal management capability deviation value Au (k) in the current sampling stage is 3.

The thermal management capability deviation value can reflect to a certain extent the difference between the current cooling output of the chillers and the thermal load demand of the system. Generally, the larger the thermal management capacity deviation value is, the larger the gap between the cooling output and the load demand is, the system regulation demand is urgent, and a quick response is required to avoid overcooling or overheating. Besides, the smaller the thermal management capacity deviation value is, the smaller the cooling output and the load demand are basically matched, the system is close to a smooth state, the regulation pressure is smaller, the operation is more efficient, and the temperature difference between the supply and return water is stable, and there is no need for drastic adjustment.

It should be noted that the setting of the fuzzy state is used in step S102 for the temperature difference and the rate of change of temperature difference, which is used to characterize the different intervals of continuous variables (such as the temperature difference and the rate of change of temperature difference, etc.) and their corresponding meanings. Based on the fact that the variables often show non-linear relationships (such as the effect of temperature difference change on cooling output), fuzzy state and fuzzy control rules can adapt to this complexity, and dynamic regulation can be realized without a precise mathematical model, which is beneficial to the subsequent precise regulation of the chiller's operating volume and chilled water output as the basic data.

Step S103, the thermal management capacity value in the current sampling stage is calculated according to the thermal management capacity deviation value in the current sampling stage and the thermal management capacity value of the previous sampling stage.

Specifically, after deriving the thermal management capability deviation value Au (k), the thermal management capability value u (k) in the current sampling stage may be calculated based on the fact that the thermal management capability value u (k) in the current sampling stage is the sum of the thermal management capability value u (k−1) in the previous sampling stage and the thermal management capability deviation value Au (k). The thermal management capacity value u (k) indirectly reflects the overall cooling output demand of the chillers of the system in the current sampling stage, and may be used as a basis for determining the number of chillers to be operated that are compatible with the current sampling stage.

Step S104, a corresponding number of chillers to be operated in the current sampling stage is determined according to the thermal management capacity value in the current sampling stage.

Specifically, after the thermal management capability value u (k) in the current sampling stage is derived, the number of chillers to be operated adapted to the current sampling stage may be derived according to a predetermined mapping relationship between the thermal management capability value u (k) and the number of chillers to be operated (as shown in Table 3 below). The number of chillers to be operated refers to the number of chillers that should be operated and are required in the current sampling stage, which serves as the first layer of basic data for the subsequent two-tier control of chillers.

TABLE 3

| Thermal | Number of | Thermal | Number of |
|---|---|---|---|
| management | chillers to | management | chillers to |
| capacity value | be operated | capacity value | be operated |
| 3 | N (full load) | −1 | N*60% (Results |
| | | | rounded to whole |
| | | | numbers) |
| 2 | N*90% (Results | −2 | N*50% (Results |
| | rounded to whole | | rounded to whole |
| | numbers) | | numbers) |
| 1 | N*80% (Results | −3 | N*40% (Results |
| | rounded to whole | | rounded to whole |
| | numbers) | | numbers) |
| 0 | N*70% (Results | / | / |
| | rounded to whole | | |
| | numbers) | | |

In Table 3, the number of chillers to be operated is the product of the number of chillers N in full load and the preset thermal management parameter, which is positively correlated with the thermal management capacity value. The corresponding number of chillers to be operated is different when the thermal management capacity value is at different values. Generally, the higher the thermal management capacity value is, the more chillers are required in this stage. For example, if the thermal management capability value u (k) in the current sampling stage is 2, the number of chillers to be operated is N*90% (the thermal management parameter is 90%). Further, if the number of chillers N in full load is 20, the corresponding number of chillers to be operated is 18.

Step S105, according to the predetermined Cooling demand control strategy, a target output cooling capacity of the chillers is determined, and each chiller in the target chillers corresponding to the number of chillers to be operated is controlled to enter into an operating state according to the target output cooling capacity, respectively.

Specifically, after determining the number of chillers to be operated in the current sampling stage, the target output cooling capacity of the operating chillers according to the preset Cooling demand control strategy is further calculated, and the target output cooling capacity is used as a second layer of basic data for subsequent two-tier control of the chillers. The number of chillers to be operated and the target output cooling capacity form two kinds of control data, and each chiller in the target chillers corresponding to the number of chillers to be operated is controlled to enter into the operating state in accordance with the target output cooling capacity, so as to carry out a synchronized two-layer control mechanism for the chillers in the loop-based thermal management system.

In summary, the embodiment of the present application is capable of realizing dynamic determination of the number of chillers to be operated in the current sampling stage and precise adjustment of the target cooling output by combining a water loop control strategy with a Cooling demand control strategy. Compared with the traditional thermal management method, the present application is able to adjust the working state of the chillers in real-time according to the load demand, which significantly improves the accuracy of the cooling capacity allocation and the system response speed, effectively avoids overcooling or undercooling, and reduces the energy consumption of the whole system, thereby providing an energy-saving effect.

In an embodiment of the present embodiment, before the step of deriving the rate of change of temperature difference according to the temperature difference in the current sampling stage and the temperature difference in the previous sampling stage, the method further includes: upon receiving a system startup command, conducting the water supply pipe loop and the water return pipe loop and starting all chillers to dissipate heat from a battery cabinet; detecting a current operating time of the all chillers, and when the current operating time is greater than or equal to a preset thermal management trigger time, performing the step of deriving the rate of change of temperature difference according to the temperature difference in the current sampling stage and the temperature difference in the previous sampling stage; wherein the thermal management trigger time is greater than a time corresponding to the current sampling stage.

Specifically, the setting of the thermal management trigger time is based on the time in the current sampling stage, and it is ensured that its value is greater than the time corresponding to the current sampling stage. For example, the thermal management trigger time may be set to 1 second, that is, after the thermal management system has been activated for 1 second, the corresponding water loop control strategy is performed, so as to ensure that the chillers exert their cooling effect for a sufficient operating time, thereby providing accurate calculations of the rate of change temperature difference for the subsequent input data. The introduction of this embodiment not only optimizes the startup logic of the chiller, but also ensures the reliability and real-time nature of the system response by presetting the trigger time, and improves the overall efficiency and accuracy of the thermal management.

In an embodiment of the present embodiment, the step of determining the target output cooling capacity of the chillers according to the predetermined Cooling demand control strategy specifically includes: calculating a percentage of cooling demand according to a preset calculation formula in the preset Cooling demand control strategy, and calculating the target output cooling capacity of the chillers according to the percentage of cooling demand and the full load output cooling capacity of the chillers.

The calculation formula is

q(k)=Kp·e(k)+Ki·Σ[e(0) . . . e(k−1)]+Ki·e(k)+Kd·[e(k)−e(k−1)];q(k)

denotes a percentage of full load output cooling capacity, and e (k) denotes a control temperature deviation of the chillers; the control temperature deviation is a difference between a controlled temperature of the chillers and a set temperature of the chillers; Kp denotes a proportionality coefficient, Ki denotes an integral coefficient, Kd denotes a differential coefficient, k denotes a serial number of the sampling stage.

Specifically, by means of the Cooling demand control strategy, the control temperature deviation (i.e., the difference between the current controlled temperature and the setting temperature) of the chiller is combined with the proportionality coefficient, the integral coefficient, and the differential coefficient, to calculate the cooling demand percentage of the chillers, and to adjust the working frequency of the compressor in the chillers according to the cooling demand percentage, so as to make the real-time output cooling capacity of the chillers in operation be the target output cooling capacity.

In an embodiment of the present embodiment, the step of controlling each of the chillers in target chillers corresponding to the number of chillers to be operated to enter into an operating state according to the target output cooling capacity specifically includes: stopping chillers in operation, selecting a number of target chillers from all chillers with the same number of the chillers to be operated, and starting the target chillers; controlling a speed of a compressor of each chiller in the target chiller according to the percentage of cooling demand so as to bring each chiller in the target chiller into operation according to the target output cooling capacity. The working frequency of the compressors is controlled according to the percentage of cooling demand to achieve the corresponding rotational speed, as shown in Table 4 below.

TABLE 4

| | Parameter | Default | | | |
|---|---|---|---|---|---|
| Parameter name | range | value | Unit | Accuracy | Note |
| Maximum cooling | 50~200 | 80 | % | 1 | / |
| capacity output of chills | | | | | |
| Minimum cooling | 10~Max. | 20 | % | 1 | / |
| capacity output of chills | frequency | | | | |
| [FM proportionality | 0.1~25.5 | 0.3 | / | 0.1 | / |
| [FM integral time Ti] | 0~255 | 60 | s | 1 | Set to 0 disables the |
| | | | | | integration |
| [FM differential time Td] | 0~255 | 0 | s | 1 | Set to 0 disables the |
| | | | | | differential |
| [FM calculation period T] | 0~255 | 1 | s | 1 | Set to 0 for |
| | | | | | fixed-frequency |
| | | | | | presses |
| [PID Single Maximum | 1~30 | 5 | % | 1 | / |
| Ramp-Up Amplitude] | | | | | |

In Table 4, it contains the compressor FM parameters (FM proportionality coefficient Kp, FM integral time Ti, FM differential time Td) used to control the output of the chillers in the Cooling demand control strategy, and the related control range and default values. These parameters are used to dynamically regulate the percentage of refrigeration demand of the chillers through the PID algorithm, thus indirectly controlling the compressor's operating frequency and operating state.

Among them,

Ki=Kp*T/Ti

and

Kd=Kp*Td/T,

that is, the compressor FM parameters are directly related to the integral coefficient and the differential coefficient in the formula of the Cooling demand control strategy. That is to say, the output cooling capacity percentage of the Cooling demand control strategy is affected by the frequency adjustment parameters of the compressor, which can realize dynamic adjustment of the compressor's working frequency, and accordingly achieve the dynamic control of the target cooling capacity output of the chillers. This closed-loop adjustment mechanism can adapt to different changes in cooling demand, realizing efficient operation and stable control of the system.

In an embodiment of the present embodiment, after stopping the chiller in operation, the method further includes: detecting the water supply pipe loop and/or the water return pipe loop; determining a target service valve corresponding to a fault area from service valves according to a fault event when the fault event occurs in the water supply pipe loop and/or the water return pipe loop; controlling the target service valve to be in a disconnected state prior to performing a service processing and controlling the target service valve to be in a conducting state after the service processing is completed. This embodiment adopts the intelligent control of fault detection and target maintenance valve, which can quickly isolate the fault area and ensure the normal operation of other system parts, greatly improving the efficiency and safety of fault handling, reducing the impact on the overall operation of the system, while providing convenient conditions for subsequent maintenance operations.

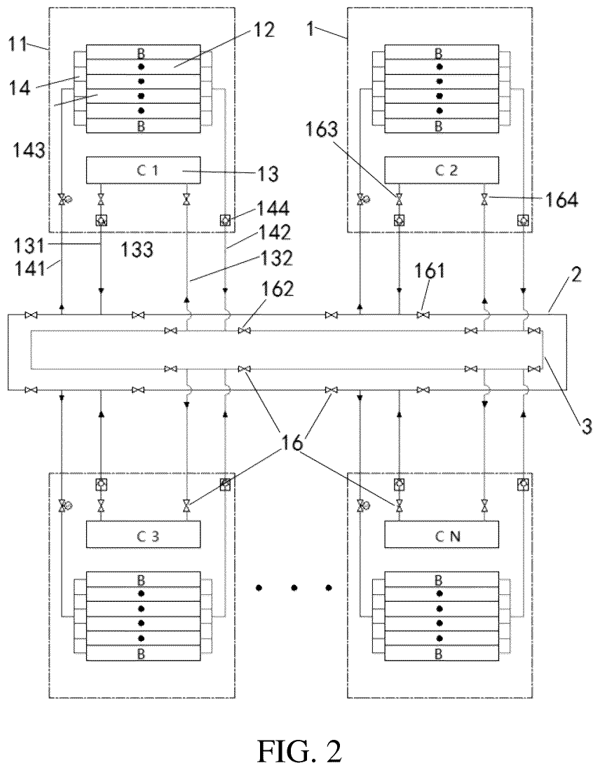

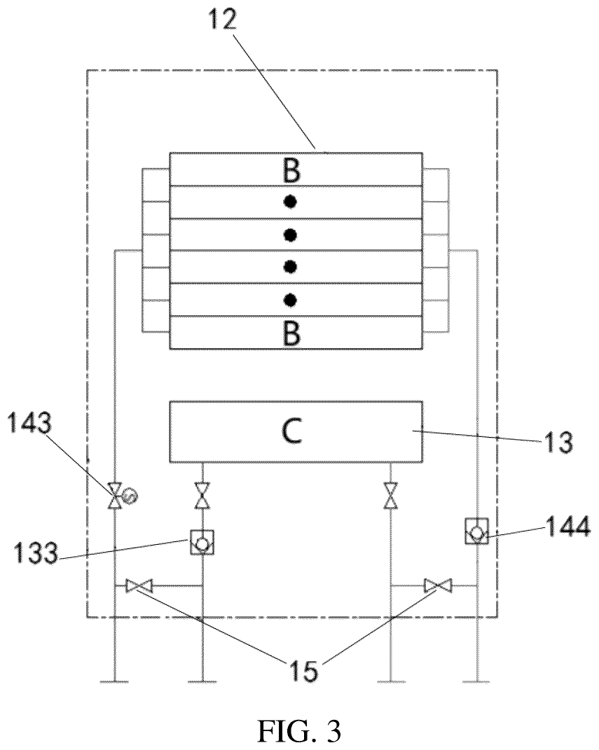

As shown in FIGS. 2 and 3, an embodiment of the present application provides a loop-based thermal management system including a battery cabinet 1, a water supply pipe loop 2, and a water return pipe loop 3. The battery cabinet 1 includes a cabinet 11, battery packs 12 (i.e., B as shown in the figures), a chiller 13, a heat dissipation group 14, and bypass valves 15. The battery pack 12, the chiller 13, the heat dissipation group 14, and the bypass valves 15 are provided in the cabinet 11, and the heat dissipation group 14 is provided on a peripheral side of the battery pack 12. A first water inlet end 141 of the heat dissipation group 14 is detachably connected to the water supply pipe loop 2, and a first water outlet end 142 of the heat dissipation group 14 is detachably connected to the water return pipe loop 3. A second water outlet end 131 of the chiller 13 is detachably connected to the water supply pipe loop 2, and a second water inlet end 132 of the chiller 13 is detachably connected to the water return pipe loop 3. A bypass valve 15 is provided between the first water inlet end 141 and the second water outlet end 131 and a bypass valve 15 is provided between the second water outlet end 142 and the second water inlet end 132.

This embodiment unites all individual thermal management systems (chillers 13) in the loop for centralized control through the water supply pipe loop 2 as well as the water return pipe loop 3. After centralized control through the water loop, the reliability of the battery cabinets 1 within the entire loop is improved, so that even if the chiller 13 within some of the battery cabinets 1 is damaged, the cooling function for the faulty battery cabinet 1 can still be provided by the other normally operating chillers 13 through the water supply pipe loop 2 as well as the water return pipe loop 3, and the battery packs 12 do not have to be shut down for continuous operation while waiting for repairs to be made. After centralized control through the water loop, in the face of most cases of some battery cabinets 1 standby, the whole chillers 13 can provide the cooling function for the remaining battery cabinets 1 in operation, to increase the heat exchanger area in disguise thereby increasing the cooling efficiency. Besides, due to the larger heat exchanger area, making the thermal management system within the loop naturally cooled for a longer and more energy-efficient period of time. By closing and opening the bypass valves 15 in the battery cabinet 1, it is possible to take into account the single operation of the battery cabinet 1 and the joint operation of many battery cabinets 1.

Specifically, as shown in FIG. 3, when a single battery cabinet 1 is operated, only the bypass valves 15 within the cabinet 11 needs to be closed to realize the separate operation of the thermal management system of the battery cabinet 1. In this circumstance, the chiller 13 within the cabinet 11 only dissipates heat from the battery packs 12 of this battery cabinet 1.

When a plurality of battery cabinets 1 form a group of battery cabinets 1 for joint operation, there are at least two battery cabinets 1, and the battery cabinets 1 are connected to each other through the water supply pipe loop 2 and the water return pipe loop 3. In this embodiment, four units are used as an example, and the operation mode has three working forms.

As shown in FIG. 1, all battery cabinets 1 are charged and discharged at the same time: the water inlet end of all battery cabinets 1 is opened, and the chillers 13 (i.e., C1, C2, C3, and CN shown in the figures) in all battery cabinets 1 are operated at a high load. The low-temperature chilled water is supplied to the battery packs 12 in all battery cabinets 1 through the water supply pipe loop 2 for heat dissipation, and the high-temperature chilled water after heat dissipation of the battery packs 12 is returned to the chillers 13 through the water return water pipe loop 3 for re-cooling output.

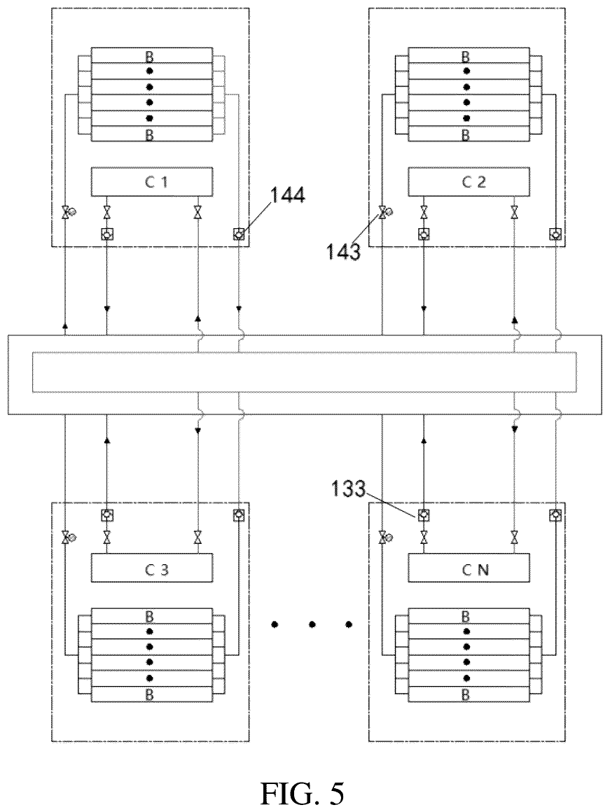

As shown in FIG. 5, some of the battery cabinets 1 (i.e., C1 shown in the figures) are in charge/discharge operation: only a portion of the battery cabinets 1 in the group of battery cabinets 1 are in charge/discharge operation most of the time. In this circumstance, the water inlet end within the non-operating battery cabinet 1 is closed, and all of the chillers 13 within the loop (i.e., C1, C2, C3, and CN shown in the figures) are operating at partial load, collectively supplying low-temperature chilled water to cool the battery cabinets 1 in operation.

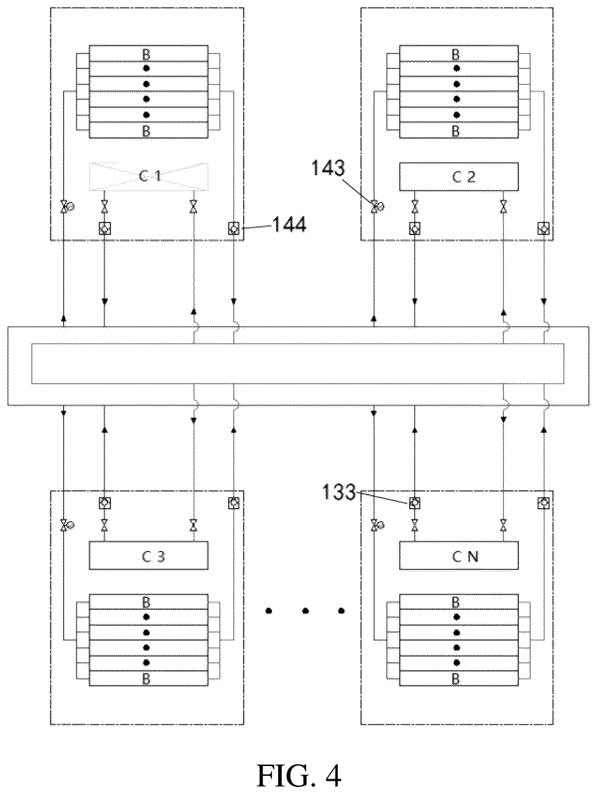

As shown in FIG. 4, a portion of the chillers 13 (i.e., C1 shown in the figures) in the battery cabinet 1 within the loop is damaged: the chiller 13 in one of the battery cabinets 1 is damaged, and the rest of the chillers 13 in the loop operates at full capacity to provide cooling for all of the battery cabinets 1 in the loop through the water supply pipe loop 2 and the water return pipe loop 3. The damaged battery cabinet 1 waits for maintenance personnel to replace the damaged chiller 13.

In practice, the chillers 13 are connected to the water supply pipe loop 2 and the water return pipe loop 3 through a piping, and the heat dissipation group 14 is connected to the water supply pipe loop 2 and the water return pipe loop 3 through the piping to facilitate the flow of liquid to help dissipate heat from the battery pack 12. The first water inlet end 141 is provided with a water inlet valve 143, which facilitates controlling the water inlet and stoppage of the first water inlet end 141. In an embodiment, the water inlet valve 143 adopts a water inlet motorized valve. The second water outlet end 131 is provided with a water outlet check valve 133 to prevent the reverse flow of liquid in the second water outlet end 131. The first water outlet end 142 is provided with a water return check valve 144 to prevent the reverse flow of liquid in the first water outlet end 142.

Further, in order to facilitate later maintenance, the pipes, the water supply pipe loop 2 and the water return pipe loop 3 are provided with service valves 16. When the chiller 13 in a certain battery cabinet 1 is damaged, the service valves 16 are utilized to close the circuit, so that the maintenance can be carried out without cutting off the working state of the other battery cabinets 1.

Specifically, the service valves 16 include a first service valve 161 provided in the water supply pipe loop 2, and located on a side of the second water outlet end 131 away from the first water inlet end 141 and/or a side of the first water inlet end 141 away from the second water outlet end 131. In practice, the first service valve 161 may be provided only on the side of the second water outlet end 131 away from the first water inlet end 141, or the first service valve 161 may be provided only on the side of the first water inlet end 141 away from the second water outlet end 131, and the number of the first service valves 161 may be increased or decreased as required. In an embodiment, the first service valves 161 are provided on the side of the second water outlet end 131 away from the first water inlet end 141 and provided on the side of the first water inlet end 141 away from the second water outlet end 131. In this circumstance, whether there is a problem with the water supply pipe loop 2 between neighboring battery cabinets 1 or a problem with the water supply pipe loop 2 of the same battery cabinet 1, the two nearest first service valves 161 can be closed to carry out maintenance, the closed loops are shorter and the impact on the loops can be minimized, which is more convenient.

The service valves 16 further include a second service valve 162 provided in the water return pipe loop 3, and located on a side of the second water inlet end 132 away from the first water outlet end 142 and/or a side of the first water outlet end 142 away from the second water inlet end 132. In practice, the second service valve 162 may be provided only on the side of the second water inlet end 132 away from the first water outlet end 142, or the second service valve 162 may be provided only on the side of the first water outlet end 142 away from the second water inlet end 132, and the number of the second service valves 162 may be increased or decreased as required. In an embodiment, the second service valves 162 are provided on the side of the second water inlet end 132 away from the first water outlet end 142 and on the side of the first water outlet end 142 away from the second water inlet end 132. In this circumstance, whether a problem occurs in the water return pipe loop 3 between neighboring battery cabinets 1 or a problem occurs in the water return pipe loop 3 of the same battery cabinet 1, the two nearest second service valves 162 can be closed to carrying out maintenance, the closed loops are shorter and the impact on the loops can be minimized, which is more convenient.

In practice, the service valves 16 further include a third service valve 163 provided between the second outlet end 131 and the water outlet check valve 133 to avoid the need to close the first service valve 161 when there is a problem with the second outlet end 131, which would result in an excessively long circuit to be closed. In this circumstance, when the second water outlet end 131 has a problem, the third service valve 163 can be closed for maintenance. Due to the water outlet check valve 133, the loop between the water outlet check valve 133 and the third service valve 163 is closed, reducing the number of the third service valves 163, which is more convenient. Besides, the closed loop is shorter, so that the impact on the loop can be minimized. It should be noted that the number of the third service valves 163 may be increased or decreased as needed.

Further, the service valves 16 further include a fourth service valve 164 provided at the second water inlet end 132 to avoid the need to close the second service valve 162 when there is a problem occurs at the second water inlet end 132, which would result in an excessively long circuit to be closed. In this circumstance, when a problem occurs at the second water inlet end 132, maintenance can be carried out by closing the fourth service valve 164. Besides, the closed circuit is shorter, so that the impact on the loop can be minimized, which is more convenient. It should be noted that the number of fourth service valves 164 may be increased or decreased as needed.

It should be noted that the service valves 16 may also be provided at other locations as needed, such as at the first water outlet end 142 or at the first water inlet end 141, etc., which are not specifically limited herein. An alarm module may also be provided, so that when a certain battery cabinet 1 or a certain number of battery cabinets 1 are malfunctioning or damaged, the maintenance personnel may be alerted by the alarm module to remind them to overhaul. The number of battery packs 12 may be increased or decreased as desired.

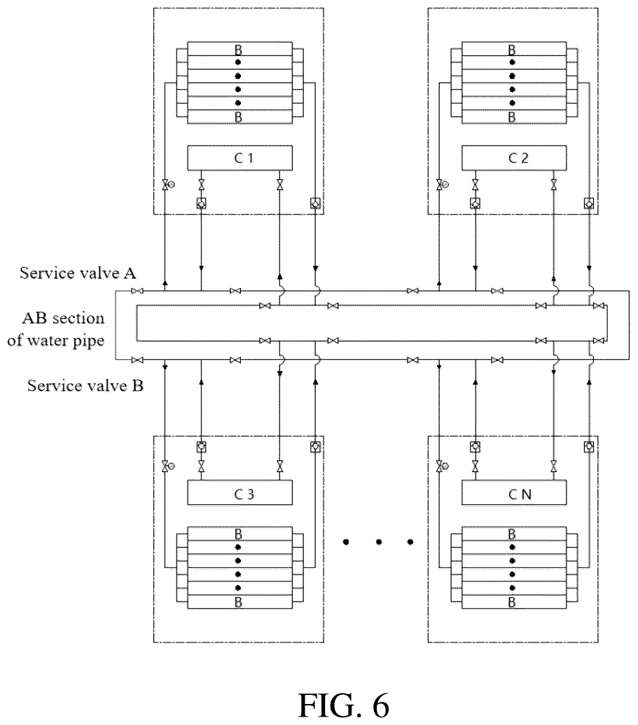

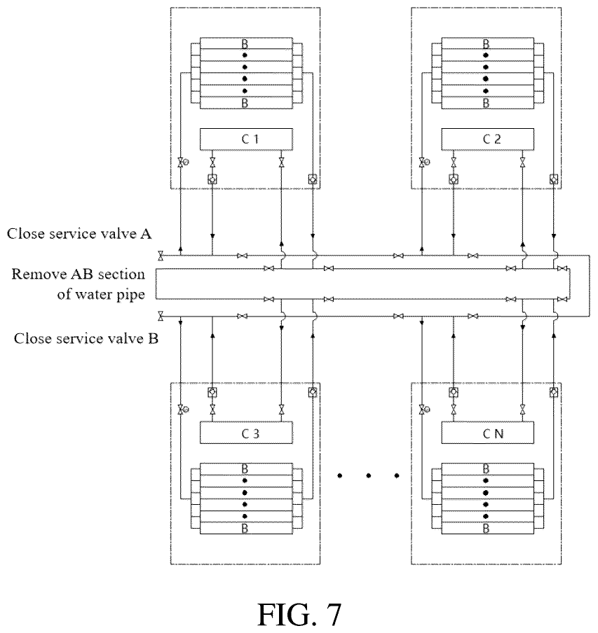

As shown in FIGS. 6 and 7, when the AB section of the water pipe (the target pipe) of the water supply pipe loop 2 is damaged and needs to be repaired, according to the target pipe, the target service valves (service valve A and service valve B) corresponding to the faulty area at both ends of the target pipe close to the target pipe are determined from a number of first service valves 161 provided in the water supply pipe loop 2. The service valve A and the service valve B are closed, and the target pipe is taken out to be repaired without affecting the normal operation of any battery cabinets within the water pipe loop. That is, in the water pipe loop, with the help of the service valves, no matter which section of the water pipe loop needs to be serviced, it is only necessary to close the service valves in the two sections of the water pipe loop in the servicing section to service the water pipe loop in a specific region without affecting the operation of the battery cabinets within the total loop.

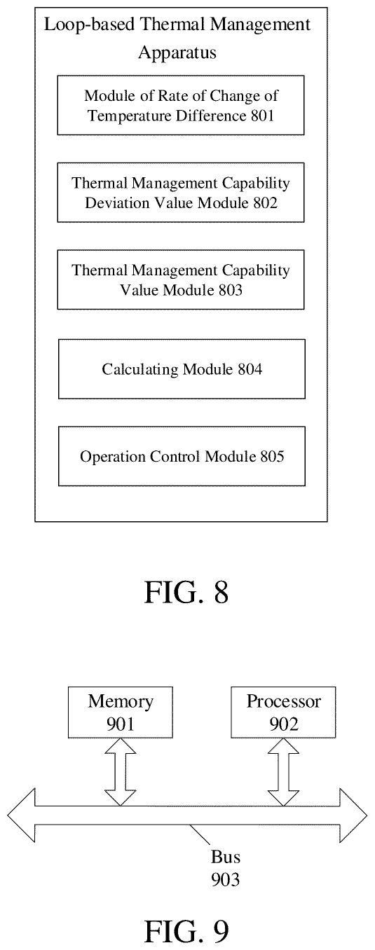

As shown in FIG. 8, illustrated is a loop-based thermal management apparatus according to an embodiment of the present application, including:

a module of rate of change of temperature difference 801 configured to derive a rate of change of temperature difference according to a temperature difference in a current sampling stage and the temperature difference in a previous sampling stage; wherein the temperature difference is a difference between a temperature of the water supply pipe loop and a temperature of the water return pipe loop;

a thermal management capability deviation value module 802 configured to determine a thermal management capacity deviation value in the current sampling stage according to the rate of change of temperature difference and the temperature difference in the current sampling stage;

a thermal management capability value module 803 configured to calculate a thermal management capacity value in the current sampling stage according to the thermal management capacity deviation value in the current sampling stage and a thermal management capacity value in the previous sampling stage;

a calculating module 804 configured to determine a corresponding number of chillers to be operated in the current sampling stage according to the thermal management capacity value in the current sampling stage; and

an operation control module 805 configured to determine a target output cooling capacity of the chillers according to a predetermined Cooling demand control strategy, and control each of the chillers in target chillers corresponding to the number of chillers to be operated to enter into an operating state according to the target output cooling capacity.

As shown in FIG. 9, illustrated is an electronic device according to an embodiment of the present application. The electronic device may be configured to implement the loop-based thermal management method in any of the preceding embodiments. The electronic device includes:

a memory 901, a processor 902, a bus 903, and a computer program stored on the memory 901 and runnable on the processor 902. The memory 901 and the processor 902 are connected through the bus 903. The processor 902 executes the computer program to implement the loop-based thermal management method of the preceding embodiment. The number of processors may be one or more.

The memory 901 may be a high-speed Random Access Memory (RAM), or it may be a non-volatile memory, such as a disk memory. The memory 901 is configured to store executable program code, and the processor 902 is connected to the memory 901.

In summary, the beneficial effects of the loop-based thermal management method, apparatus, device, and system of the present application are as follows. Firstly, by combining a water loop control strategy with a Cooling demand control strategy, it is possible to determine the number of chillers to be operated and the target output cooling capacity that are compatible with the current sampling stage, and thus control the number of chillers to be operated and the output cooling capacity of the corresponding chillers on the basis of the confirmed data, so as to realize precise adjustment. In other words, compared with the traditional thermal management method, the present application is able to adjust the working state of the chillers in real-time according to the heat dissipation situation inside the loop and the load demand, significantly improving the accuracy of the cooling capacity distribution and the system response speed, effectively avoid overcooling or undercooling, and reduce the energy consumption of the whole system, thus achieving the energy-saving effect. Secondly, through the water supply pipe loop as well as the water return pipe loop, all the individual heat management systems (chillers) within the loop are united for centralized control. After the centralized control through the water loop, the reliability of the battery cabinets in the whole loop is improved, even if some of the chillers in the battery cabinets are damaged, they can still be used to provide cooling for the faulty battery cabinets through the water supply pipe loop and the water return pipe loop by other chillers in normal operation, so that the battery packs do not have to shut down and continue to run while waiting for the repair process. After centralized control through the water loop, in the face of most cases of some battery cabinets standby, the whole chillers can provide the cooling function for the remaining battery cabinets in operation, to increase the heat exchanger area in disguise thereby increasing the cooling efficiency. Besides, due to the larger heat exchanger area, making the thermal management system within the loop naturally cooled for a longer and more energy-efficient period of time. By closing and opening the bypass valves in the battery cabinet, it is possible to take into account the single operation of the battery cabinet and the joint operation of many battery cabinets.

In the several embodiments provided in the present application, it should be understood that the apparatuses and methods disclosed, may be realized in other ways. For example, the apparatus embodiments described above are merely schematic, e.g., the division of modules is only a logical functional division, and may be divided in other ways in actual implementation. For example, multiple modules or components may be combined or may be integrated into another system, or some features may be ignored, or not implemented. Another point is that the mutual coupling or direct coupling or communication connection shown or discussed may be indirect coupling or communication connection through some interface, device or module, which may be electrical, mechanical or other forms.

The modules illustrated as separate components may or may not be physically separate, and the components shown as modules may or may not be physical modules, i.e., they may be located in a single place or they may be distributed to a plurality of network modules. Some or all of these modules may be selected to fulfill the purpose of the embodiment scheme according to actual needs.

In addition, the various functional modules in the various embodiments of the present application may be integrated in a single processing module, or the individual modules may be physically present separately, or two or more modules may be integrated in a single module. The above integrated modules may be implemented either in the form of hardware or in the form of software function modules.

The integrated modules, when implemented in the form of software function modules and sold or used as separate products, may be stored in a computer-readable storage medium. According to this understanding, the technical solution of the present application may be embodied, in essence or as a contribution to the prior art, or in whole or in part, in the form of a software product, which is stored in a computer-readable storage medium and includes a number of instructions to enable a computer device (which may be a personal computer, a server, or a network device, etc.) to perform all or part of the steps of the method of the various embodiments of the present application. The aforementioned readable storage medium includes a USB flash drive, a removable hard disk, a ROM, a RAM, a diskette, a CD-ROM, and other media that can store program code.

It should be noted that the aforementioned method embodiments are expressed as a series of action combinations for the sake of simplicity of description, but the person skilled in the art should be aware that the present application is not limited by the order of the described actions. According to the present application, some of the steps may be carried out in a different order or at the same time. Secondly, the person skilled in the art should also be aware that the embodiments described in the specification are preferred embodiments, and the actions and modules involved are not necessarily necessary for the present application.

In the above embodiments, the description of each embodiment has its own focus, and the part that is not described in detail in a certain embodiment may be referred to as the relevant description of other embodiments.

Described above are only embodiments of the present application, and are not intended to limit the scope of the patent of the present application. Any equivalent structure or equivalent process transformations utilizing the specification and the accompanying drawings of the present application, or directly or indirectly applying them in other related technical fields, are all reasonably included in the scope of the patent protection of the present application.

What is claimed is:

1. A loop-based thermal management method, applied to a loop-based thermal management system comprising a water supply pipe loop, a water return pipe loop, and a plurality of chillers, the loop-based thermal management method comprising:
deriving a rate of change of temperature difference according to a temperature difference in a current sampling stage and the temperature difference in a previous sampling stage; wherein the temperature difference is a difference between a temperature of the water supply pipe loop and a temperature of the water return pipe loop;
determining a thermal management capacity deviation value in the current sampling stage according to the rate of change of temperature difference and the temperature difference in the current sampling stage;
calculating a thermal management capacity value in the current sampling stage according to the thermal management capacity deviation value in the current sampling stage and a thermal management capacity value in the previous sampling stage;
determining a corresponding number of chillers to be operated in the current sampling stage according to the thermal management capacity value in the current sampling stage; and
determining a target output cooling capacity of the chillers according to a predetermined Cooling demand control strategy, and controlling each of the chillers in target chillers corresponding to the number of chillers to be operated to enter into an operating state according to the target output cooling capacity.

2. The loop-based thermal management method of claim 1, wherein before the step of deriving the rate of change of temperature difference according to the temperature difference in the current sampling stage and the temperature difference in the previous sampling stage, the method further comprises:
upon receiving a system startup command, conducting the water supply pipe loop and the water return pipe loop, and starting all chillers to dissipate heat from a battery cabinet;
detecting a current operating time of the all chillers, and when the current operating time is greater than or equal to a preset thermal management trigger time, performing the step of deriving the rate of change of temperature difference according to the temperature difference in the current sampling stage and the temperature difference in the previous sampling stage;
wherein the thermal management trigger time is greater than a time corresponding to the current sampling stage.

3. The loop-based thermal management method of claim 1, wherein the step of determining the thermal management capacity deviation value in the current sampling stage according to the rate of change of temperature difference and the temperature difference in the current sampling stage comprises:
determining a first fuzzy state corresponding to the rate of change of temperature difference and a second fuzzy state corresponding to the temperature difference in the current sampling stage, respectively, according to a predetermined mapping relationship between the rate of change of temperature difference and a fuzzy state and a predetermined mapping relationship between the temperature difference and the fuzzy state;
according to the first fuzzy state and the second fuzzy state, and in combination with a predetermined mapping relationship between the fuzzy state and the thermal management capability deviation value, determining the thermal management capability deviation value in the current sampling stage.

4. The loop-based thermal management method of claim 1, wherein the step of determining the corresponding number of chillers to be operated in the current sampling stage according to the thermal management capacity value in the current sampling stage comprises:
determining the number of chillers to be operated corresponding to the thermal management capacity value in the current sampling stage according to a mapping relationship between the predetermined thermal management capacity value and the number of chillers to be operated;
wherein the number of chillers to be operated is the product of the number of full-loaded chillers and a predetermined thermal management parameter, and the thermal management parameter is positively correlated with the thermal management capacity value.

5. The loop-based thermal management method of claim 1, wherein the step of determining the target output cooling capacity of the chillers according to the predetermined Cooling demand control strategy comprises:
calculating a percentage of cooling demand according to a preset calculation formula in the preset Cooling demand control strategy; wherein the calculation formula is
q(k)=Kp·e(k)+Ki·Σ[e(0) . . . e(k−1)]+Ki·e(k)+Kd·[e(k)−e(k−1)];q(k)
denotes a percentage of full load output cooling capacity, and e (k) denotes a control temperature deviation of the chillers; the control temperature deviation is a difference between a controlled temperature of the chillers and a set temperature of the chillers; Kp denotes a proportionality coefficient, Ki denotes an integral coefficient, Kd denotes a differential coefficient, and k denotes a serial number of the sampling stage;
calculating the target output cooling capacity of the chillers according to the percentage of cooling demand and the full load output cooling capacity of the chillers.

6. The loop-based thermal management method of claim 5, wherein the step of controlling each of the chillers in target chillers corresponding to the number of chillers to be operated to enter into an operating state according to the target output cooling capacity comprises:
stopping chillers in operation, selecting a number of target chillers from all chillers with the same number of the chillers to be operated, and starting the target chillers;
controlling a speed of a compressor of each chiller in the target chillers according to the percentage of cooling demand so as to bring each chiller in the target chillers into operation according to the target output cooling capacity.

7. The loop-based thermal management method of claim 6, wherein after the step of stopping the chillers in operation, the method further comprises:
detecting the water supply pipe loop and/or the water return pipe loop;
determining a target service valve corresponding to a fault area from service valves according to a fault event when the fault event occurs in the water supply pipe loop and/or the water return pipe loop;
controlling the target service valve to be in a disconnected state prior to performing a service processing and controlling the target service valve to be in a conducting state after the service processing is completed.

8. An electronic device, comprising a memory, a processor, and a bus;
wherein the bus is configured to realize a connection communication between the memory and the processor;
the processor is configured to execute a computer program stored in the memory;
and the processor, when executing the computer program, realizes the steps in the loop-based thermal management method of claim 1.

9. A loop-based thermal management system, comprising:
a battery cabinet, comprising a cabinet, a battery pack, chillers, a heat dissipation group, and bypass valves;
a water supply pipe loop; and
a water return pipe loop;
wherein the battery pack, the chillers, the heat dissipation group, and the bypass valves are provided in the cabinet, and the heat dissipation group is provided on a peripheral side of the battery pack; a first inlet end of the heat dissipation group is detachably connected to the water supply pipe loop, and a first water outlet end of the heat dissipation group is detachably connected to the water return pipe loop; a second water outlet end of the chillers is detachably connected to the water supply pipe loop, and a second water inlet end of the chillers is detachably connected to the water return pipe loop; a by-pass valve is provided between the first water inlet end and the second water outlet end, and a by-pass valve is provided between the first water outlet end and the second water inlet end;
wherein the loop-based thermal management system is configured to realize the steps in the loop-based thermal management method of claim 1.

10. The loop-based thermal management system of claim 9, wherein there are at least two battery cabinets, and the battery cabinets are connected to each other through the water supply pipe loop and the water return pipe loop; a water inlet valve is provided at the first water inlet end, a water outlet check valve is provided at the second water outlet end, and a water return check valve is provided at the first water outlet end; the chillers are in conduction with the water supply pipe loop and the water return pipe loop through a piping, and the heat dissipation group is in conduction with the water supply pipe loop and the water return pipe loop through the piping; the piping, the water supply pipe loop, and the water return pipe loop are all provided with service valves.

11. The loop-based thermal management system of claim 10, wherein the service valves comprise a first service valve, a second service valve, a third service valve, and a fourth service valve, wherein the first service valve is provided in the water supply pipe loop, and located on a side of the second outlet end away from the first inlet end and/or a side of the first inlet end away from the second outlet end; the second service valve is provided in the water return pipe loop, and located on a side of the first outlet end away from the first inlet end and/or a side of the first outlet end away from the second inlet end; the third service valve is provided between the second outlet end and the water outlet check valve, and the fourth service valve is provided at the second inlet end.
